(19) United States
(12) Patent Application Publication
(10) Pub. No.: US 2011/0180791 A1
(43) Pub. Date: Jul. 28, 2011

(54) COPOLYMER FOR ELECTRONIC DEVICES

(75) Inventors: Junyou Pan, Frankfurt am Main (DE); Frank Egon Meyer, Hampshire (GB)

(73) Assignee: Merck Patent Gesellschaft Mit Beschrankter Haftung, Darmastadt (DE)

(21) Appl. No.: 13/062,800

(22) PCT Filed: Aug. 12, 2009
(86) PCT No.: PCT/EP2009/005848

§ 371 Date: Mar. 8, 2011

(30) Foreign Application Priority Data
Sep. 9, 2008 (EP) 08015835.5

(51) Int. Cl. H01L 51/46; H01L 51/30

(52) U.S. Cl. 257/40; 257/E51.028

(57) ABSTRACT

The invention relates to the use of a copolymer comprising indenofluorene units as charge transport material in the charge transport layer of a non-electroluminescent electronic device, especially a photoreceptor or electrophotographic device, and to charge transport layers and electronic devices, especially photoreceptors and electrophotographic devices, comprising such a copolymer.

### FIELD OF THE INVENTION

The invention relates to the use of a copolymer comprising indenofluorene units as charge transport material in the charge transport layer of a non-electroluminescent electronic device, especially a photoreceptor or electrophotographic device, and to charge transport layers and electronic devices, especially photoreceptors and electrophotographic devices, comprising such a copolymer.

### Background and Prior Art

Since the first electrophotographic machines were developed in 1938, they have found widespread use in document processing. Most of the copiers and printers nowadays used in offices are based on this technology. Owing to its great commercial value, considerable research effort has been devoted to electrophotography and relevant materials.

The key component in an electrophotographic device is the photoreceptor, on which the electrostatic latent images will be generated, which are then transferred onto paper. The entire electrophotographic process comprises the steps of charging of the photoreceptor, imagewise discharge of the photoreceptor, development by toner, transferring the toner image to a sheet of paper, and fixing the toner on the paper by fusing (see Paul M. Borsenberger; David S. Weiss Organic Photorecptors for Xerography; Marcel Dekker, Inc., 1998, Chapter1).

The photoreceptor usually consists of a charge generation layer (CGL), in which free charge carriers are generated upon illumination under an electric field, and a charge transport layer (CTL), in which the free charge carriers are transported to discharge at the surface. The CTL essentially determines the discharge speed and thus the printing speed of the device, the mechanical robustness and the chemical stability.

In electrophotographic devices of the negative charge type, hole transport materials (HTM) are used as charge transport material (CTM) in the CTL. A typical, widely used organic CTL comprises a mixture of a binding polymer and a CTM, wherein the binding polymer provides the mechanical robustness and the CTM provides the charge transport function. For example, organic systems like polycarbonate (PC) doped with N,N′-Diphenyl-N,N′-bis-(3-methylphenyl)-(1,1′-biphenyl)-4,4′-diamine (TPD) have been successfully used in the CTL of such devices.

However, in such devices it was observed that the charge carrier mobility of the above-mentioned organic systems is limited. For example, in case of a device comprising 20-50% TPD in PC, the hole mobility is only around 10⁻⁶ cm²/Vs⁻¹. Moreover, the chemical and electronical stability of such organic systems is also limited.

For high speed printing systems a CTL with high charge carrier mobility is required, and a long lifetime is also desired. Moreover, it is also strongly desired, especially for mass production, to use a one-component organic system instead of a mixture.

It is therefore an aim of the present invention to find alternative and improved materials for electrophotographic devices, in particular improved HTL materials for electrophotographic devices of the negative charge type, which, in particular, have high hole mobility and are suitable for a high performance printing system. Another aim is to extend the pool of CTL materials for use in electrophotographic devices available to the expert. Other aims of the present invention are immediately evident to the expert from the following detailed description.

In another embodiment, the present invention is related to other non-light emitting electronic devices, especially organic solar cell, dye-sensitized solar cell, field quench device and spintronic device.

The inventors of the present invention have found that these aims can be achieved by providing organic materials and non-electroluminescent electronic devices as described hereinafter.

### SUMMARY OF THE INVENTION

The invention relates to an electronic device, preferably a non-electroluminescent electronic device, comprising

an electrode,
a functional layer provided on the said electrode,
characterized in that the said functional layer comprises a copolymer comprising at least one repeat unit of formula I

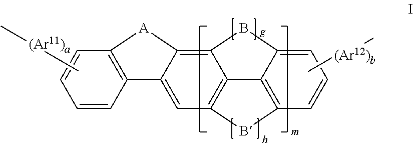

wherein
A, B and B′ are independently of each other, and in case of multiple occurrence independently of one another, a divalent group, preferably selected from —CR¹R²—, —NR¹—, —PR¹—, —O—, —S—, —SO—, —SO₂—, —CO—, —CS—, —CSe—, —P(═O)R¹—, —P(═S)R¹— and —SiR¹R²—,
R¹ and R² are independently of each other identical or different groups selected from H, halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂, —CF₃, —SF₅, optionally substituted silyl, or carbyl or hydrocarbyl with 1 to 40 C atoms that is optionally substituted and optionally contains one or more hetero atoms, and optionally the groups R¹ and R² form a spiro group with the fluorene moiety to which they are attached,
X is halogen,
R⁰ and R⁰⁰ are independently of each other H or an optionally substituted carbyl or hydrocarbyl group optionally containing one or more hetero atoms,
each g is independently one of 0 and 1 and each corresponding h in the same subunit is the other of 0 and 1,
m is an integer 1,
Ar¹¹ and Ar¹² are independently of each other mono- or polynuclear aryl or heteroraryl that is optionally substituted and optionally fused to the 7,8-positions or 8,9-positions of the indenofluorene group,
a and b are independently of each other 0 or 1,

Preferably, the said functional layer has charge transport or charge generation function or both.

Preferably, the said non-electroluminescent electronic device contains only one electrode.

Preferably, the said non-electroluminescent electronic device comprises a charge generation layer provided between the said electrode and the functional layer, wherein the CGL generates free charge carriers upon optical excitation optionally, and preferably, under an electric field.

Preferably, the said non-electroluminescent electronic device is a photoreceptor or a electrophotographic device, very preferably a negative charge device, wherein most preferably the said functional layer is a hole transport layer.

Preferably, the said copolymer further comprises at least one repeat unit having hole transport property selected from the group consisting of amines, triarylamines, thiophenes, pyroles, anilines and their derivatives. Preferably, the said copolymer is a regular alternating copolymer comprising 50% units A and 50% units B, wherein A is a repeat unit of formula I, and B is a repeat unit having hole transport property.

The invention further relates to a non-electroluminescent electronic device comprising

an electrode,
a counter electrode, and
a functional layer provided between the said electrodes,
characterized in that the said functional layer comprises a copolymer comprising at least one repeat unit according to formula I.

Preferably the said copolymer comprises one or more further charge transport units selected from the group consisting of amines, triarylamines, thiophenes, pyroles, anilines and their derivatives.

Very preferably the said copolymer is an alternating copolymer.

Preferably, the said non-electroluminescent electronic device comprises a charge generation layer between the functional layer and any of said electrodes.

Preferably said non-electroluminescent electronic device is an organic solar cell, a dye-sensitized solar cell (DSSC), a field quench device, a spintronic device, a photoreceptor or an electrophotographic device.

The invention further relates to the use of a copolymer as described above and below in a non-electroluminescent electronic device as described above and below, and to a charge transport layer of an electronic device comprising a copolymer as described above and below.

### BRIEF DESCRIPTION OF THE DRAWINGS

FIG. 1 exemplarily shows a single-layer electrophotographic device according to the present invention, wherein layer 4 comprises a copolymer according to the present invention.

FIG. 2 exemplarily shows a double-layer electrophotographic device according to the present invention.

FIG. 3 shows the photo-induced discharge curve (PIDC) of an electrophotographic device according to Example 1 of the present invention.

FIG. 4 shows the quantum yield of photogeneration of free charge carriers in an electrophotographic device according to Example 1 of the present invention using Polymer 1 as HTM.

FIG. 5 shows the quantum yield of photogeneration of free charge carriers in an electrophotographic device according to Example 1 of the present invention using Polymer2 as HTM.

### DEFINITION OF TERMS

“Electronic device” means a device involving optical and/or electronic/electrical processes, for example having optical input and electrical output, or vice versa.

“Charge generation layer” means a layer which can generate the free charge carriers under electric field upon the physical excitation, for example optical, or thermal, or electromagnetic excitation, for example the charge generation layer in an electrophotographic device, which comprises for example phthalocaynines, dye-sensitized TiO₂ in a dye-sensitised solar cell, and conjugated polymers doped with fullerene derivatives in organic solar cells. The electric field can be an externally applied electric field, for example in electrophotographic device or a built-in electric field in solar cells.

“Backbone unit” means a unit that has the highest content (in mol %, unless stated otherwise) of all units present in a copolymer. Backbone units can also form electron transport units or hole transport units alone or in combination with other units. For example, if there are two units whose contents are clearly higher than those of the other units present in the copolymer, or if there are only two units present in a copolymer, then both groups are considered as backbone units. Preferably the backbone units are electron transport units.

“Unit” means a monomer unit or repeating unit in a polymer or copolymer.

“Polymer” includes homopolymers and copolymers, e.g. statistical, alternating or block copolymers. In addition, the term “polymer” as used hereinafter does also include dendrimers, which are typically branched macromolecular compounds consisting of a multifunctional core group onto which further branched monomers are added in a regular way giving a tree-like structure, as described for example in M. Fischer and F. Vögtle, Angew. Chem., Int. Ed. 1999, 38, 885.

“Conjugated polymer” means a polymer containing in its backbone (or main chain) mainly C atoms with sp²-hybridisation (or optionally also sp-hybridisation), which may also be replaced by hetero atoms. In the simplest case this is for example a backbone with alternating C—C single and double (or triple) bonds, but does also include polymers with units like 1,3-phenylene. “Mainly” means in this connection that a polymer with naturally (spontaneously) occurring defects, which may lead to interruption of the conjugation, is still regarded as a conjugated polymer. Also included in this meaning are polymers wherein the backbone comprises for example units like aryl amines, aryl phosphines and/or certain heterocycles (i.e. conjugation via N-, O-, P- or S-atoms) and/or metal organic complexes (i.e. conjugation via a metal atom).

Unless stated otherwise, groups or indices like Ar, R¹⁻⁴, n etc. in case of multiple occurrence are selected independently from each other and may be identical or different from each other. Thus, several different groups might be represented by a single label like “R¹”.

“Aryl” or “arylene” means an aromatic hydrocarbon group or a group derived from an aromatic hydrocarbon group. “Heteroaryl” or “heteroarylene” means an “aryl” or “arylene” group comprising one or more hetero atoms. The terms “alkyl”, “aryl”, “heteroaryl” etc. also include multivalent species, for example alkylene, arylene, heteroarylene etc.

“Carbyl/carbon group” means any monovalent or multivalent organic radical moiety which comprises at least one carbon atom either without any non-carbon atoms (like for example —C≡C—), or optionally combined with at least one non-carbon atom such as N, O, S, P, Si, Se, As, Te or Ge (for example carbonyl etc.). “Hydrocarbyl/hydrocarbon group” means a carbyl or carbon group that additionally contains one or more H atoms and optionally contains one or more hetero atoms like for example N, O, S, P, Si, Se, As, Te or Ge.

A carbyl or hydrocarbyl group comprising a chain of 3 or more C atoms may be linear, branched and/or cyclic, including spiro and/or fused rings.

### DETAILED DESCRIPTION OF THE INVENTION

Preferably the copolymer is a conjugated copolymer comprising two or more different repeating units. At least one of these units is a unit of formula I, which preferably serves as polymer backbone. At least one other of these units is a monomeric unit different from formula I, which preferably serves as charge transport material.

Very preferred are units of formula I wherein the groups R¹ and R² form a spiro group with the fluorene group to which they are attached.

If in the units of formula I the groups R¹ and R² form a spiro group with the fluorene group to which they are attached, it is preferably spirobifluorene.

Preferably the units of formula I are selected from the group consisting of the following subformulae:

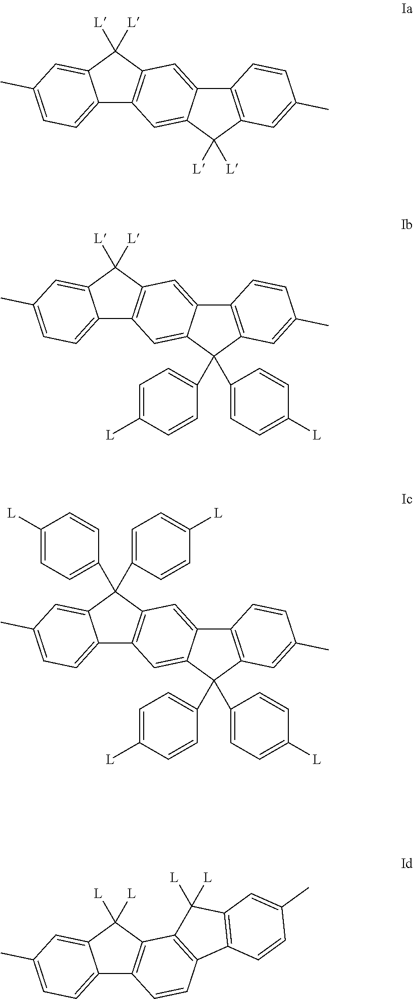

wherein
L is selected from H, halogen or optionally fluorinated, linear or branched alkyl or alkoxy with 1 to 12 C atoms or an optionally substituted aryl or heteroaryl group with 1 to 40 C atoms, and is preferably H, F, methyl, i-propyl, t-butyl, n-pentoxy, or trifluoromethyl, and
L′ is optionally fluorinated, linear or branched alkyl or alkoxy with 1 to 12 C atoms or an optionally substituted aryl or heteroaryl group with 1 to 40 C atoms, and is preferably n-octyl or n-octyloxy.

Preferably the copolymer comprises, in addition to the units of formula I, one or more units selected from formula II:

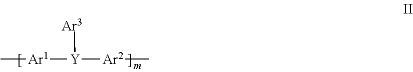

wherein
Y is N, P, P═O, PF₂, P═S, As, As═O, As═S, Sb, Sb═O or Sb═S, preferably N,
Ar¹ which may be the same or different, denote, independently if in different repeat units, a single bond or an optionally substituted mononuclear or polynuclear aryl or heteroaryl group,
Ar² which may be the same or different, denote, independently if in different repeat units, an optionally substituted mononuclear or polynuclear aryl or heteroaryl group,
Ar³ which may be the same or different, denote, independently if in different repeat units, an optionally substituted mononuclear or polynuclear aryl or heteroaryl group,
m is 1, 2 or 3.

Especially preferred units of formula II are selected from the group consisting of the following subformulae:

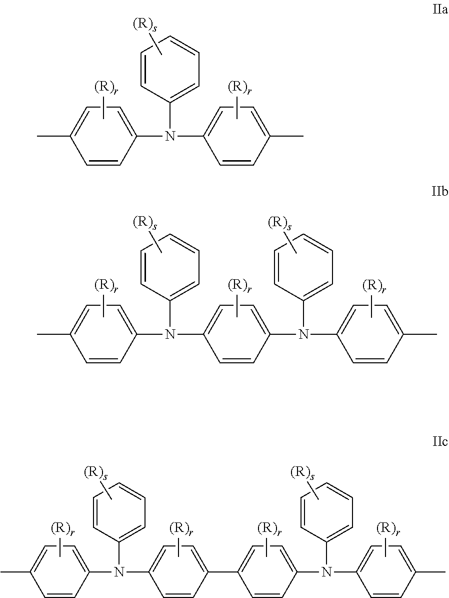

wherein
R which may be the same or different in each occurrence, is selected from H, substituted or unsubstituted aromatic or heteroaromatic group, alkyl, cycloalkyl, alkoxy, aralkyl, aryloxy, arylthio, alkoxycarbonyl, silyl, carboxy group, a halogen atom, cyano group, nitro group or hydroxy group,
r is 0, 1, 2, 3 or 4, and
s is 0, 1, 2, 3, 4 or 5.

The units of formula II serve as hole transport unit.

In another preferred embodiment of the present invention, the said copolymer comprises, in addition to the units of formula I, one or more further repeat units selected of formula III, in addition or alternatively to the units of formula II:

—(T¹)_{c}—(Ar⁴)_{d}—(T²)ₑ—(Ar⁵)_{f}— III

wherein
T¹ and T² are independently of each other selected from thiophene, selenophene, thieno[2,3b]thiophene, thieno[3,2b]thiophene, dithienothiophene, pyrrole, aniline, all of which are optionally substituted with R⁵,
R⁵ is in each occurrence independently of each other selected from halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂, —CF₃, —SF_{S}, optionally substituted silyl, or carbyl or hydrocarbyl with 1 to 40 C atoms that is optionally substituted and optionally contains one or more hetero atoms,
Ar⁴ and Ar⁵ are independently of each other mononuclear or polynuclear aryl or heteroaryl, which is optionally substituted and optionally fused to the 2,3-positions of one or both of the adjacent thiophene or selenophene groups,
c and e are independently of each other 0, 1, 2, 3 or 4, with 1<c+e≦6,
d and f are independently of each other 0, 1, 2, 3 or 4.

The units of formula III serve as hole transport unit.

The copolymer of the present invention may be a statistical, random, alternating, regioregular or block copolymer or any combination thereof. It may comprise two, three or more distinct monomer units.

The content of units of formula I in the copolymer is preferably >5 mol % and ≦100 mol %, very preferably from to 20 to 80 mol %, very preferably from 40 to 60 mol %.

The content of units of formula II in the copolymer is preferably >0 mol %, very preferably >5 mol %, and preferably <95 mol %, very preferably from to 20 to 80 mol %, very preferably from 40 to 60 mol %.

The content of units of formula III in the copolymer is preferably >0 mol % and <95 mol %, very preferably from to 20 to 80 mol %, very preferably from 40 to 60 mol %.

In another preferred embodiment, the copolymer comprises, in addition to the units of formula I and in addition or alternatively to the units of formula II and/or III, further repeating units selected from anthracene, benz-anthracene, ketone, carbazole, fluorene, spirobifluorene, phenathrene, dehydrophenanthrene, triazine imidazole, pyridine, pyrimidine, pyridazine, pyrazine, oxadiazole, quinoline, quinoxaline, pyrene, perylene, benz-imidazole, phosphinoxide, phenazine, phenanthroline, triarylborane and their derivatives, all of which are optionally substituted.

The copolymer is preferably selected of the following formula

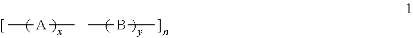

wherein x and y denote the molar ratio of the monomeric units,
A is, in each case identically or different from each other, a unit of formula I as defined above,
B is, in each case identically or different from each other, a unit of formula II or III as defined above or selected from the other repeating units as mentioned above,
x is >0.05 and <1,
y is >0 and <0.95,
x+y is 1,
n is an integer >1.

Preferred copolymers of formula I are selected from the following subformulae

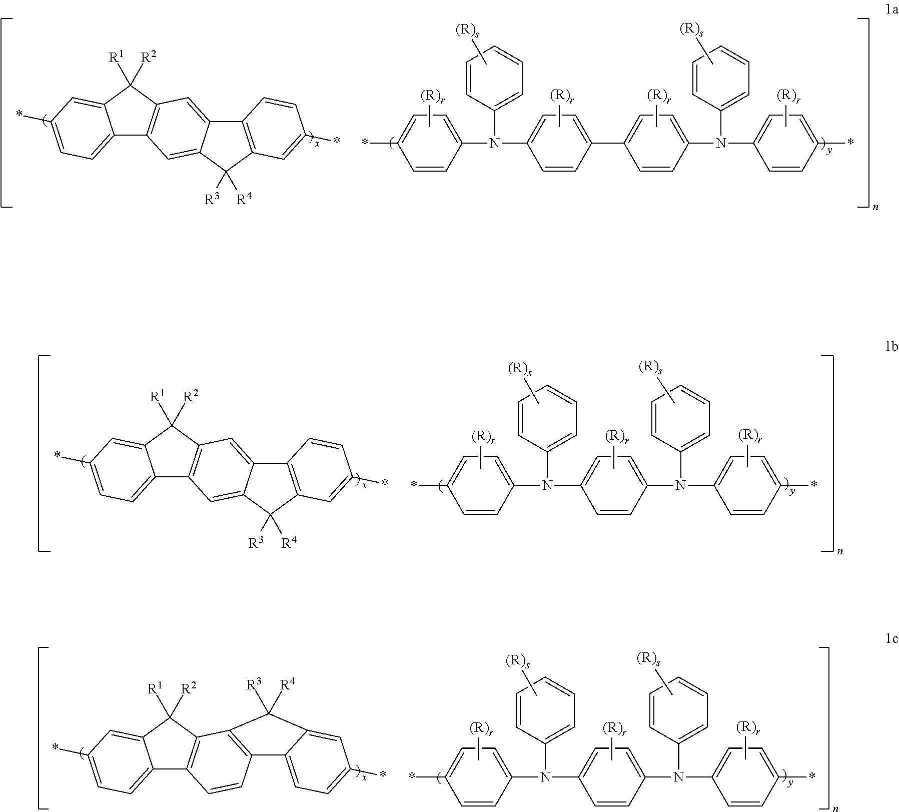

wherein R^{1,2} are as defined in formula I, R, r and s are as defined in formula IIa, x, y and n are as defined in formula I, and R³ and R⁴ independently of each other have one of the meanings of R¹ in formula I.

In the copolymer of formula I, very preferably 0.4<x<0.6 and 0.6<y<0.4, most preferably x=y=0.5.

Preferred carbyl and hydrocarbyl groups include alkyl, alkoxy, alkylcarbonyl, alkoxycarbonyl, alkylcarbonyloxy and alkoxycarbonyloxy, each of which is optionally substituted and has 1 to 40, preferably 1 to 25, very preferably 1 to 18 C atoms, furthermore optionally substituted aryl or aryloxy having 6 to 40, preferably 6 to 25 C atoms, furthermore alkylaryl, arylalkyl, alkylaryloxy, arylalkyloxy arylcarbonyl, aryloxycarbonyl, arylcarbonyloxy and aryloxycarbonyloxy, each of which is optionally substituted and has 6 to 40, preferably 6 to 25 C atoms.

The carbyl or hydrocarbyl group may be a saturated or unsaturated acyclic group, or a saturated or unsaturated cyclic group. Unsaturated acyclic or cyclic groups are preferred, especially alkenyl and alkynyl groups (especially ethynyl). Where the C₁-C₄₀ carbyl or hydrocarbyl group is acyclic, the group may be linear or branched.

The C₁-C₄₀ carbyl or hydrocarbyl group includes for example: C₁-C₄₀ alkyl, C₂-C₄₀ alkenyl, C₂-C₄₀ alkynyl, C₃-C₄₀ alkyl group, C₄-C₄₀ alkyldienyl, C₄-C₄₀ polyenyl, C₆-C₄₀ aryl, C₆-C₄₀ alkylaryl, C₆-C₄₀ arylalkyl, C₆-C₄₀ alkylaryloxy, C₆-C₄₀ arylalkyloxy, C₆-C₄₀ heteroaryl, C₄-C₄₀ cycloalkyl, C₄-C₄₀ cycloalkenyl, and the like. Very preferred are C₁-C₂₀ alkyl, C₂-C₂₀ alkenyl, C₂-C₂₀ alkynyl, C₃-C₂₀ alkyl, C₄-C₂₀ alkyldienyl, C₆-C₁₂ aryl, C₆-C₂₀ arylalkyl and C₆-C₂₀ heteroaryl.

Further preferred carbyl and hydrocarbyl groups include straight-chain, branched or cyclic alkyl with 1 to 40, preferably 1 to 25 C-atoms, which is unsubstituted, mono- or polysubstituted by F, Cl, Br, I or CN, and wherein one or more non-adjacent CH₂ groups are optionally replaced, in each case independently from one another, by —O—, —S—, —NH—, —NR⁰—, —SiR⁰R⁰⁰—, —CO—, —COO—, —COO—, —O—CO—O—, —S—CO—, —CO—S—, —SO₂—, —CO—NR⁰—, —NR⁰—CO—, —NR⁰—CO—NR⁰⁰—, —CX¹═CX²— or —C≡C— in such a manner that O and/or S atoms are not linked directly to one another, with R⁰ and R⁰⁰ having one of the meanings given as described above and below and X¹ and X² being independently of each other H, F, Cl or CN.

R⁰ and R⁰⁰ are preferably selected from H, straight-chain or branched alkyl with 1 to 12 C atoms or aryl with 6 to 12 C atoms.

Halogen is F, Cl, Br or I.

Preferred alkyl groups include, without limitation, methyl, ethyl, n-propyl, i-propyl, n-butyl, i-butyl, s-butyl, t-butyl, 2-methylbutyl, n-pentyl, s-pentyl, cyclopentyl, n-hexyl, cyclohexyl, 2-ethylhexyl, n-heptyl, cycloheptyl, n-octyl, cyclooctyl, dodecanyl, trifluoromethyl, perfluoro-n-butyl, 2,2,2-trifluoroethyl, perfluorooctyl, perfluorohexyl etc.

Preferred alkenyl groups include, without limitation, ethenyl, propenyl, butenyl, pentenyl, cyclopentenyl, hexenyl, cyclohexenyl, heptenyl, cycloheptenyl, octenyl, cyclooctenyl etc.

Preferred alkynyl groups include, without limitation, ethynyl, propynyl, butynyl, pentynyl, hexynyl, octynyl etc.

Preferred alkoxy groups include, without limitation, methoxy, ethoxy, 2-methoxyethoxy, n-propoxy, i-propoxy, n-butoxy, i-butoxy, s-butoxy, t-butoxy, 2-methylbutoxy, n-pentoxy, n-hexoxy, n-heptoxy, n-octoxy etc.

Preferred amino groups include, without limitation, dimethylamino, methylamino, methylphenylamino, phenylamino, etc.

Aryl groups may be mononuclear, i.e. having only one aromatic ring (like for example phenyl or phenylene), or polynuclear, i.e. having two or more aromatic rings which may be fused (like for example napthyl or naphthylene), individually covalently linked (like for example biphenyl), and/or a combination of both fused and individually linked aromatic rings.

Preferably the aryl group is an aromatic group which is substantially conjugated over substantially the whole group.

Preferred aryl groups include, without limitation, benzene, biphenylene, triphenylene, [1,1′:3′,1″]terphenyl-2′-ylene, naphthalene, anthracene, binaphthylene, phenanthrene, pyrene, dihydropyrene, chrysene, perylene, tetracene, pentacene, benzpyrene, fluorene, indene, indenofluorene, spirobifluorene, etc.

Preferred heteroaryl groups include, without limitation, 5-membered rings like pyrrole, pyrazole, imidazole, 1,2,3-triazole, 1,2,4-triazole, tetrazole, furan, thiophene, selenophene, oxazole, isoxazole, 1,2-thiazole, 1,3-thiazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 6-membered rings like pyridine, pyridazine, pyrimidine, pyrazine, 1,3,5-triazine, 1,2,4-triazine, 1,2,3-triazine, 1,2,4,5-tetrazine, 1,2,3,4-tetrazine, 1,2,3,5-tetrazine, and fused systems like indole, isoindole, indolizine, indazole, benzimidazole, benzotriazole, purine, naphthimidazole, phenanthrimidazole, pyridimidazole, pyrazinimidazole, quinoxalinimidazole, benzoxazole, naphthoxazole, anthroxazole, phenanthroxazole, isoxazole, benzothiazole, benzofuran, isobenzofuran, dibenzofuran, quinoline, isoquinoline, pteridine, benzo-5,6-quinoline, benzo-6,7-quinoline, benzo-7,8-quinoline, benzoisoquinoline, acridine, phenothiazine, phenoxazine, benzopyridazine, benzopyrimidine, quinoxaline, phenazine, naphthyridine, azacarbazole, benzocarboline, phenanthridine, phenanthroline, thieno[2,3b]thiophene, thieno[3,2b]thiophene, dithienothiophene, isobenzothiophene, dibenzothiophene, benzothiadiazothiophene, or combinations thereof. The heteroaryl groups may be substituted with alkyl, alkoxy, thioalkyl, fluoro, fluoroalkyl or further aryl or heteroaryl substituents.

Preferred arylalkyl groups include, without limitation, 2-tolyl, 3-tolyl, 4-tolyl, 2,6-dimethylphenyl, 2,6-diethylphenyl, 2,6-di-1-propylphenyl, 2,6-di-t-butylphenyl, o-t-butylphenyl, m-t-butylphenyl, p-t-butylphenyl, 4-phenoxyphenyl, 4-fluorophenyl, 3-carbomethoxyphenyl, 4-carbomethoxyphenyl etc.

Preferred alkylaryl groups include, without limitation, benzyl, ethylphenyl, 2-phenoxyethyl, propylphenyl, diphenylmethyl, triphenylmethyl or naphthalinylmethyl.

Preferred aryloxy groups include, without limitation, phenoxy, naphthoxy, 4-phenylphenoxy, 4-methylphenoxy, biphenyloxy, anthracenyloxy, phenanthrenyloxy etc.

The aryl, heteroaryl, carbyl and hydrocarbyl groups optionally comprise one or more substitutents, preferably selected from silyl, sulpho, sulphonyl, formyl, amino, imino, nitrilo, mercapto, cyano, nitro, halogen, C₁₋₁₂alkyl, C₆₋₁₂ aryl, C₁₋₁₂ alkoxy, hydroxy and/or combinations thereof. The optional substituents may comprise all chemically possible combinations in the same group and/or a plurality (preferably two) of the aforementioned groups (for example amino and sulphonyl if directly attached to each other represent a sulphamoyl radical).

Preferred substituents include, without limitation, solubilising groups such as alkyl or alkoxy, electron withdrawing groups such as fluorine, nitro or cyano, and substituents for increasing glass transition temperature (Tg) of the polymer such as bulky groups, e.g. tert-butyl or optionally substituted aryl groups.

Preferred substituents include, without limitation, F, Cl, Br, I, —CN, —NO₂, —NCO, —NCS, —OCN, —SCN, —C(═O)NR⁰R⁰⁰, —C(═O)X, —C(═O)R⁰, —NR⁰R⁰⁰, wherein R⁰, R⁰⁰ and X are as defined above, optionally substituted silyl, aryl with 4 to 40, preferably 6 to 20 C atoms, and straight chain or branched alkyl, alkoxy, alkylcarbonyl, alkoxycarbonyl, alkylcarbonlyoxy or alkoxycarbonyloxy with 1 to 20, preferably 1 to 12 C atoms, wherein one or more H atoms are optionally replaced by F or Cl.

In the (co)polymers according to the present invention, the number of repeating units n is preferably from 10 to 10,000, very preferably from 50 to 5,000, most preferably from 50 to 2,000.

The (co)polymers of the present invention may be prepared by any suitable method. For example, they can be suitably prepared by aryl-aryl coupling reactions, such as Yamamoto coupling, Suzuki coupling, Stille coupling, Sonogashira coupling or Heck coupling. Suzuki coupling and Yamamoto coupling are especially preferred.

The monomers which are polymerised to form the repeat units of the (co)polymers of the present invention can be prepared according to suitable methods which are known to the expert and have been disclosed in the literature. Suitable and preferred methods for the preparation of indenofluorene monomers are described for example in WO 2004/041901 and EP2004006721. Suitable and preferred methods for the preparation of triarylamine monomers are described for example in WO 99/54385.

Preferably the (co)polymers are prepared from monomers comprising one of the above mentioned groups, which are linked to two polymerisable groups P. Accordingly, for example the indenofluorene monomers are selected of the following formula

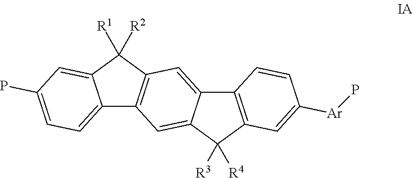

wherein P is a polymerisable group and Ar, R¹⁻⁴ are as defined above. The other co-monomers, like e.g. triarylamine monomers, are built accordingly.

Preferably the groups P are independently of each other selected from Cl, Br, I, O-tosylate, O-triflate, O-mesylate, O-nonaflate, SiMe₂F, SiMeF₂, O—SO₂, B(OZ¹)₂, —CZ²═C(Z²)₂, —C≡CH and Sn(Z³)₃, wherein Z and Z¹⁻³ are selected from the group consisting of alkyl and aryl, each being optionally substituted, and two groups Z¹ may also form a cyclic group.

Preferred methods for polymerisation are those leading to C—C-coupling or C—N-coupling, like Suzuki polymerisation, as described for example in WO 00/53656, Yamamoto polymerisation, as described in for example in T. Yamamoto et al., Progress in Polymer Science 1993, 17, 1153-1205 or in WO 2004/022626 A1, and Stille coupling. For example, when synthesizing a linear polymer by Yamamoto polymerisation, a monomer as described above having two reactive halide groups P is preferably used. When synthesizing a linear polymer by Suzuki polymerisation, preferably a monomer as described above is used wherein at least one reactive group P is a boron derivative group.

Suzuki polymerisation may be used to prepare regioregular, block and random copolymers. In particular, random copolymers may be prepared from the above monomers wherein one reactive group P is halogen and the other reactive group P is a boron derivative group. Alternatively, block or regioregular copolymers, in particular AB copolymers, may be prepared from a first and a second of the above monomers wherein both reactive groups of the first monomer are boron and both reactive groups of the second monomer are halide. The synthesis of block copolymers is described in detail for example in WO 2005/014688 A2.

Suzuki polymerisation employs a Pd(0) complex or a Pd(II) salt. Preferred Pd(0) complexes are those bearing at least one phosphine ligand such as Pd(Ph₃P)₄. Another preferred phosphine ligand is tris(ortho-tolyl)phosphine, i.e. Pd(o-Tol)₄. Preferred Pd(II) salts include palladium acetate, i.e. Pd(OAc)₂. Suzuki polymerisation is performed in the presence of a base, for example sodium carbonate, potassium phosphate or an organic base such as tetraethylammonium carbonate. Yamamoto polymerisation employs a Ni(0) complex, for example bis(1,5-cyclooctadienyl) nickel(0).

As alternatives to halogens as described above, leaving groups of formula —O—SO₂Z can be used wherein Z is as described above. Particular examples of such leaving groups are tosylate, mesylate and triflate.

A further aspect of the present invention relates to an organic material, layer or component, in particular a charge transport layer in an non-electroluminescent electronic device containing only one electrode, comprising an organic material as described above and below.

A further aspect is the use of the organic material as described above and below in a photoreceptor or an electrophotographic device. Very preferably the photoreceptor includes a charge generation layer between the said electrod and the said functional layer that is a charge transport layer, which has a free surface for charging by physical methods, preferably by Corona charge, and wherein preferably the charging is provided directly on one surface of the said functional layer. Very preferably the charge transport layer is a hole transport layer.

Preferably, the said first electronic device is a photoreceptor or an electrophotographic device, which works upon optical excitation.

A further aspect of the present invention relates to a second non-electroluminescent electronic device comprising:

an electrode,
a counter electrode, and
a functional layer provided between the said electrodes,
characterized in that the said functional layer comprises a copolymer as described above and below.

Preferably the said copolymer comprises one or more further charge transport units selected from amines, triarylamines, thiophenes, pyroles, anilines and their derivatives.

Very preferably the copolymer is an alternating copolymer.

Preferably, the said second non-electroluminescent electronic device comprises a charge generation layer between the functional layer and any of the said electrodes.

Preferably said second non-electroluminescent electronic device is an organic solar cell or dye-sensitized solar cell (DSSC). A typical DSSC structure comprises, in this sequence, a transparent electrode, a dye-sensitized TiO2 layer (CGL), a hole transport media, and a counter electrode (see e.g. U. Bach et al., Nature 395, 583-585 (1991).

Further preferably said second non-electroluminescent electronic device is a field quench device. A typical field quench device comprises, in this sequence, an electrode, a functional layer comprising a photo-luminescent or electroluminescent material, and a counter electrode, wherein the photoluminescence or electroluminescence from the function layer is controllably quenched by applying an external electric field through the electrodes, as disclosed for example in US 2004-017148 A1.

Further preferably said second non-electroluminescent electronic device is a spintronic device. In general, a spintronic device is any device which can manipulate the spin of the electron, and/or transport and/or store electron with specific spin, and/or detect the spin state of the electron. In the present invention, the spintronic device is preferably related to an organic spin valve. One typical structure of an organic spin valve comprises two ferromagnetic electrodes and an organic layer between the two ferromagnetic electrodes (see Z. H. Xiong et al., in Nature 2004 Vol 427 pp 821). Preferably at least one of the organic layers comprises a copolymer as described above and below and the ferromagnetic electrode is composed of Co, Ni, Fe, or alloys thereof, or ReMnO₃ or CrO₂, wherein Re is rare earth element.

The organic material of the present invention is typically processed in the device to form a organic layer or film, preferably less than 200 microns thick. Typically the layer is at most 1 micron (=1 μm) thick, although it may be thicker if required. For various electronic device applications, the thickness may range from less than about 1 micron to several tens micron thick. For use in an electrophotographic device, the layer thickness is preferably from 10 to 100 microns. For use in DSSC, the layer thickness is typically from 10 to 200 nm.

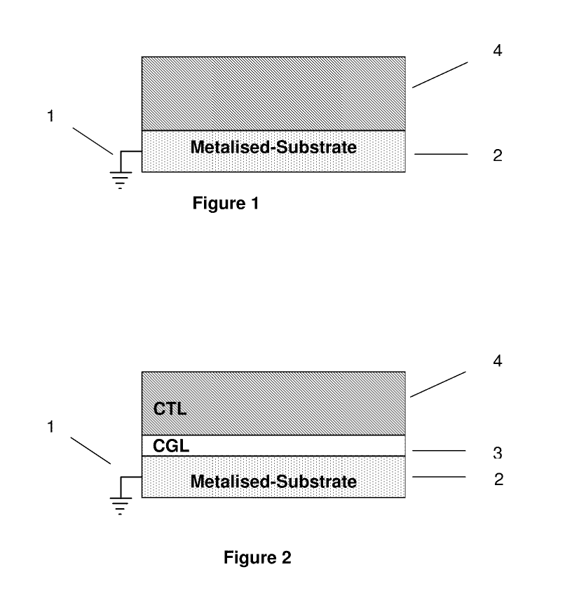

A typical single-layer photoreceptor for electrophotographic application according to the present invention is shown in FIG. 1, comprising:
a contact to ground (1),
a metalised substrate (2) as electrode, e.g. a metal coated glass or plastic substrate, preferably the metal is Al,
a charge transport layer (4) (CTL)
   wherein the CTL (4) comprises a copolymer as described above and below.

A typical double-layer photoreceptor for electrophotographic application according to the present invention is shown in FIG. 2, comprising:
a contact to ground (1),
a metalised substrate (2) as electrode, e.g. a metal coated glass or plastic substrate, preferably the metal is Al,
a charge generation layer (3) (CGL),
a charge transport layer (4) (CTL)
   wherein the CTL (4) comprises a copolymer as described above and below.

The standard device components and suitable materials and methods their manufacture are known from the literature and described for example in Paul M. Borsenberger; David S. Weiss Organic Photorecptors for Xerography; Marcel Dekker, Inc., 1998, and K. Y. Law, Chem. Rev. Vol 93, 449-486 (1993).

The CGL is required to generate free charge carrier efficiently upon illumination, thus to comprise charge generation material (CGM) having strong absorption at the desired wavelength and high dissociation probability of the exciton. In general, the polymers suitable for organic solar cells, as summarized for example by F. C. Krebs, in Solar Energy Materials and Solar Cells, Vol 91, pp 953 (2007), or dyes for dye-sensitized solar cells, for example ruthenium complexes as disclosed by Yu Bai et. al., in Nature Materials, Vol 7, pp 626 (2008) and by B. O'Regan et. al., in Nature 353, 737 (1991), are also suitable for CGM in the present invention. Preferably, the CGM is selected from AZO, phthalocaynine, including metal-free phthalocaynines, donor or accepotor doped metal-free phthalocaynines and metal phthalocyanines, porphyrins, squaraine, perylene pigments as summarized by Paul M. Borsenberger; David S. Weiss Organic Photorecptors for Xerography; Marcel Dekker, Inc., 1998, Chapter 6, and K. Y. Law, Chem. Rev. Vol 93, 449-486 (1993); Further preferable polymeric CGMs are selected from popolysilanes, polygermanes, polymer(N-vinylcarbazole) (PVK) and related compounds, triphenylamine and tri-tolyamine doped polymers, and PVK-TNF (Trinitrofluorenone) charge-transfer complex. Further preferable CGMs are selected from organic compounds containing fused ring system, for example anthracene, naphthalene, pentacene and tetracene derivatives.

For deposition in double-layer photoreceptors, the CGM is preferably dissolved or dispersed in a solvent that is orthogonal to the solvent used for depositing the CTM. Furthermore, an additive polymer is preferably added to the solution or dispersion to improve the mechanical and film formation properties.

Another aspect of the invention relates to a formulation, preferably a solution, comprising a copolymer as described above and below and one or more organic solvents.

Examples of suitable and preferred organic solvents include, without limitation, dichloromethane, trichloromethane, monochlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, dimethylformamide, dimethylacetamide, dimethylsulfoxide, tetralin, decalin, indane and/or mixtures thereof.

The concentration of the copolymer in the solution is preferably 0.1 to 10% by weight, more preferably 0.5 to 5% by weight.

For use as CTL layer the copolymer of the present invention may be deposited by any suitable method. Liquid coating of organic electronic devices such as organic photoreceptors, organic solar cells and DSSCs is more desirable than vacuum deposition techniques. Solution deposition methods are especially preferred. Preferred deposition techniques include, without limitation, spray coating, dip coating, spin coating, ink jet printing, letter-press printing, screen printing, doctor blade coating, roller printing, reverse-roller printing, offset lithography printing, flexographic printing, web printing, brush coating, pad printing or slot-die coating. Spray coating and dip coating are particularly preferred for organic photoreceptors as they allow high materials usage, high put-through for thick layers.

The copolymer or formulation according to the present invention can additionally comprise one or more further components like for example surface-active compounds, lubricating agents, wetting agents, dispersing agents, hydrophobing agents, adhesive agents, flow improvers, defoaming agents, deaerators, diluents which may be reactive or non-reactive, auxiliaries, colourants, dyes or pigments, sensitizers, stabilizers, nanoparticles or inhibitors.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention. Independent protection may be sought for these features in addition to or alternative to any invention presently claimed.

The invention will now be described in more detail by reference to the following examples, which are illustrative only and do not limit the scope of the invention.

Unless stated otherwise, all specific values of physical parameters like photoinduced-discharge curves, dark decay curves, quantum yield of photogeneration of free charge carriers, as given above and below refer to a temperature of 25° C. (+/−1° C.). Ratios of monomers or repeating units in polymers are given in mol %. The molecular weight of polymers is given as weight average molecular weight M_{w} (GPC, polystyrene standard).

### Example 1

### Materials

The following alternating copolymers, Polymerl and Polymer2, were prepared by Suzuki coupling as disclosed in WO03/048225 A1.

Polymerl is prepared from the monomers in the ratios below (in mol %):

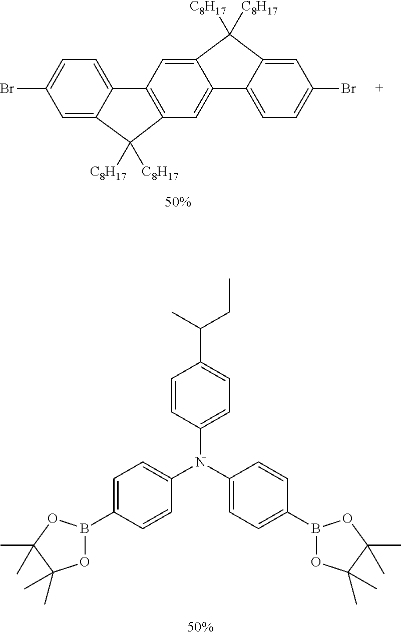

Polymer2 is prepared from the monomers in the ratios below (in mol %):

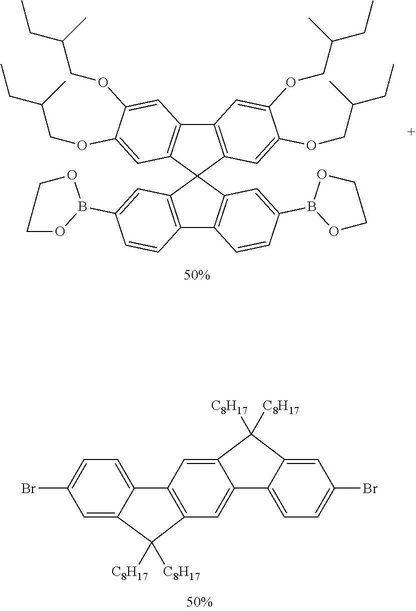

Polymerl has an Mw of about 300 kg/mol. Polymer2 has an Mw of 387.5 kg/mol The copolymers were e used as hole transport material (HTM) in the CTL of an electrophotographic device.

A mixture of polycarbonate (PC) doped with N,N′-Diphenyl-N,N′-bis-(3-methylphenyl)-(1,1′-biphenyl)-4,4′-diamine (TPD) 20 wt % is also used as control HTM.

A dispersion comprising 4.2% CGM, 1.8% Polyvinylbutyral, 47% Ethylacetat and 47% Butylacetat is received from Sensient Imaging Technologies GmbH Germany, and used as received, wherein “CGM” is a charge generation material of the following formula (Y—TiO-Phthalocyanine complex=“Y—TiOPc”):

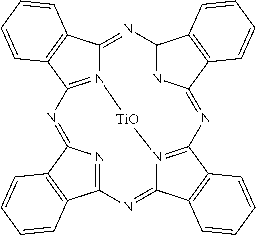

The dispersion can be used in the charge generation layer (CGL) of an electrophotographic device.

### Example 2

### Device Structure and Preparation

A double-layer electrophotographic device with a structure as shown in FIG. 2 is prepared as follows:

1) An electrode is prepared by evaporating a 200 nm Al layer on a glass substrate;
2) A CGL is prepared by coating a 150-200 nm layer of the TiOPc dispersion of Example 1 on the Al electrode and then heated for 10 minutes at 180° C. to remove the residual solvents;
3) A CTL is prepared by coating a solution of the copolymers (Polymerl and Polymer2) or the control mixture PC:20% TPD of Example 1 (30 mg/ml) in toluene by doctor blade technique onto the Y—TiOPc layer and heated for 60 minutes at 180° C. to remove the residual solvent. A layer thickness of about 10 μm is obtained.

### Example 3

### Electrophotography Measurements

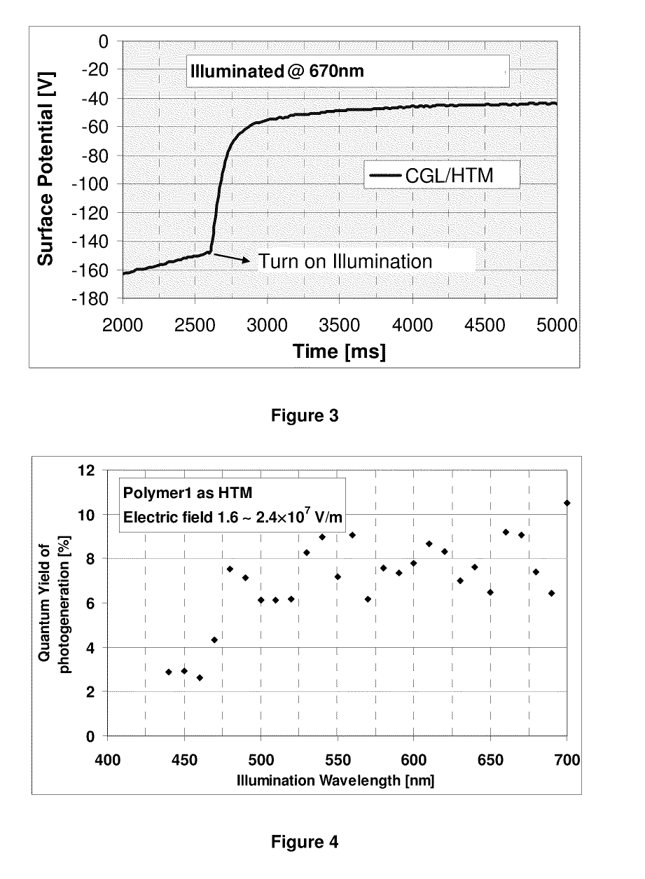

The details of electrophotographic setup and measurements are also described elsewhere by Pan et al., J. Chem. Phys. (2000) Vol. 112, pp 4305: The dark-adapted devices of example 2, with its electrode grounded, is charged by a Corona charger to a certain surface potential; The device is then exposed with monochromatic radiation incident on the free surface. The exposure is realized using a setup consisting of a monochromator equipped with a 150 W Xenon lamp. The surface potential is measured by a non-contact electrostatic voltmeter. By xerographic measurements the so-called photo-induced discharge curve is obtained, a typical example is shown in FIG. 3. Under emission-limited condition, the photogeneration efficiency φ can be calculated by the following equation:

$$φ = - \frac{{ɛɛ}_{o}}{d \cdot {I}_{o}} {( \frac{d V}{d t} )}_{{V}_{i}} \qquad ( 1 )$$

Where ∈ is the dielectric constant, d the sample thickness, l₀ the photon flux, and Vᵢ the surface potential at the onset of illumination.

A typical PIDC and dark decay of the device of Example 2 using polymer 1 as HTM in CTL are shown in FIG. 3. It shows that a very rapid photo-induced discharge (a complete discharge within about 0.5 s) can be realised by using Polymerl as CTM, the dark decay is about 20V/s, which can be further reduced by device optimisation.

The quantum yield of photogeneration of free charge carriers in the device of using Polymerl as CTM is very high, in average about 8% in illumination wavelength from 600-800 nm at the electric field of 1.6-2.4×10⁷ V/m, and is shown in FIG. 4.

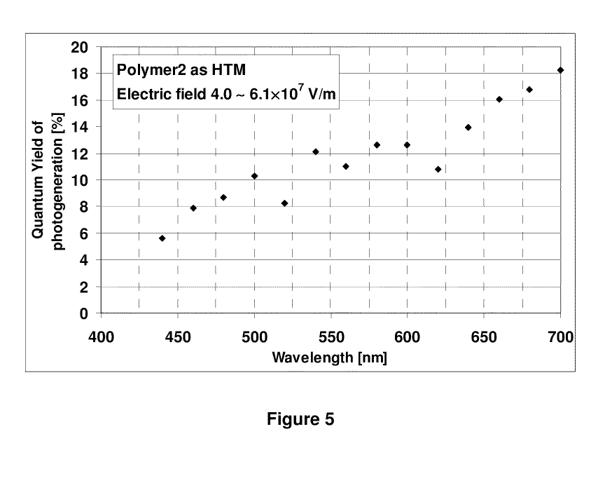

FIG. 5 shows the quantum yield of photogeneration of free charge carriers in the device using Polymer2 as HTM at an electric field of 4.0−6.1×10⁷ V/m. The quantum yield is even higher than the device using Polymer 1, but care should be taken for the different electric fields. However, Polymer2 shows a littler higher dark decay rate about 45V/s in comparison with Polymerl.

In comparison with Polymerl and Polymer2, the control device using PC:20% TPD as HTM shows a slower photo-induced curves and lower quantum yield in the whole measurement range with a maximum about 6%, indicating that Polymerl and Polymer2 according to the present invention are excellent HTM suitable for electrophotography devices.

1. A non-electroluminescent electronic device comprising
an electrode,
a functional layer provided on the electrode,
characterized in that functional layer comprises a copolymer comprising at least one repeat unit of formula I 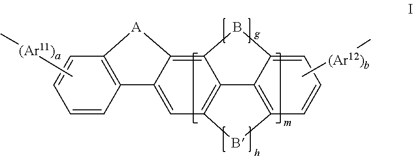
wherein
A, B and B′ are independently of each other, and in case of multiple occurrence independently of one another, a divalent group, preferably selected from —CR¹R²—, —NR¹—, —PR¹, —O, S, SO, SO₂—, —CO—, —CS—, —CSe—, —P(═O)R¹—, —P(═S)R¹— and —SiR¹R²—,
R¹ and R² are independently of each other identical or different groups selected from H, halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂, —CF₃, —SF₅, optionally substituted silyl, or carbyl or hydrocarbyl with 1 to 40 C atoms that is optionally substituted and optionally contains one or more hetero atoms, and optionally the groups R¹ and R² form a spiro group with the fluorene moiety to which they are attached,
X is halogen,
R⁰ and R⁰⁰ are independently of each other H or an optionally substituted carbyl or hydrocarbyl group optionally containing one or more hetero atoms,
each g is independently one of 0 or 1 and each corresponding h in the same subunit is the other of 0 or 1,
m is an integer ≧1,
Ar¹¹ and Ar¹² are independently of each other mono- or polynuclear aryl or heteroraryl that is optionally substituted and optionally fused to the 7,8-positions or 8,9-positions of the indenofluorene group,
a and b are independently of each other 0 or 1,

2. A device according to claim 1, wherein the said functional layer has charge transport function or charge generation function or both;

3. A device according to claim 1, characterized in that a charge generation layer (CGL) is provided between the said function layer and the said electrode, wherein the CGL generates free charge carriers upon optical excitation, optionally under an electric field.

4. A device according to claim 1, wherein the function layer is a hole transport layer

5. A device according to claim 1, wherein the function layer is an electron transport layer

6. A device according to claim 1, which is a photoreceptor or electrophotographic device, characterized in that the device has a free surface for charging by physical methods, preferably by Corona charge, wherein preferably the charging is provided directly on one surface of the said functional layer.

7. A device according to claim 1, wherein the units of formula I are selected from the group consisting of the following subformulae: 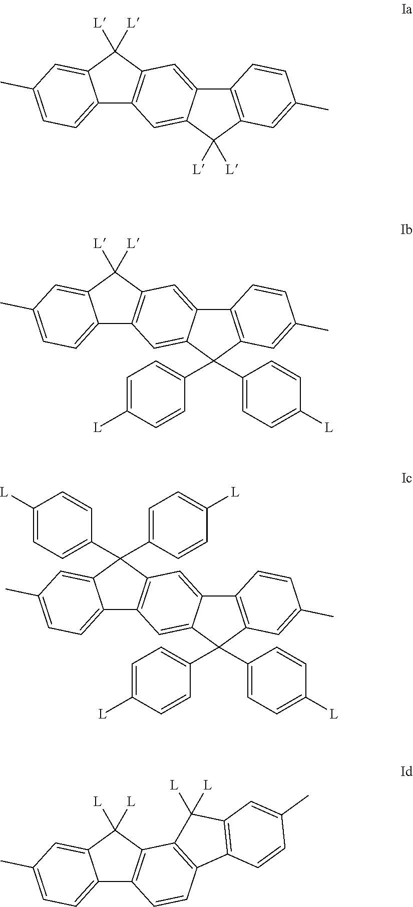
wherein
L is selected from H, halogen or optionally fluorinated, linear or branched alkyl or alkoxy with 1 to 12 C atoms or an optionally substituted aryl or heteroaryl group with 1 to 40 C atoms, and
L′ is optionally fluorinated, linear or branched alkyl or alkoxy with 1 to 12 C atoms, or an optionally substituted aryl or heteroaryl group with 1 to 40 C atoms.

8. A device according to claim 1, characterized in that the copolymer additionally comprises one or more units selected from formula II: 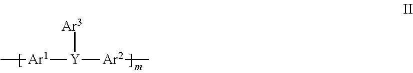
wherein
Y is N, P, P═O, PF₂, P═S, As, As═O, As═S, Sb, Sb═O or Sb, S, preferably N,
Ar¹ which may be the same or different, denote, independently if in different repeat units, a single bond or an optionally substituted mononuclear or polynuclear aryl or heteroaryl group,
Ar² which may be the same or different, denote, independently if in different repeat units, an optionally substituted mononuclear or polynuclear aryl or heteroaryl group,
Ar³ which may be the same or different, denote, independently if in different repeat units, an optionally substituted mononuclear or polynuclear aryl or heteroaryl group,
m is 1, 2 or 3.

9. A device according to claim 8, characterized in that the units of formula II are selected from the group consisting of the following subformulae: 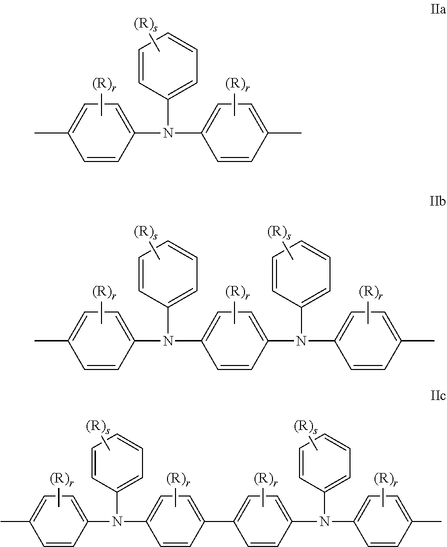
wherein
R which may be the same or different in each occurrence, is selected from H, substituted or unsubstituted aromatic or heteroaromatic group, alkyl, cycloalkyl, alkoxy, aralkyl, aryloxy, arylthio, alkoxycarbonyl, silyl, carboxy group, a halogen atom, cyano group, nitro group or hydroxy group,
r is 0, 1, 2, 3 or 4, and
s is 0, 1, 2, 3, 4 or 5.

10. A device according to claim 1, characterized in that the copolymer comprises one or more repeat units selected from formula III:
—(T¹)_{c}—(Ar⁴)_{d}—(T²)ₑ—(Ar⁵)_{f}— III
wherein
T¹ and T² are independently of each other selected from thiophene, selenophene, thieno[2,3b]thiophene, thieno[3,2b]thiophene, dithienothiophene and pyrrole, all of which are optionally substituted with R⁵,
R⁵ is in each occurrence independently of each other selected from halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂, —CF₃, —SF_{S}, optionally substituted silyl, or carbyl or hydrocarbyl with 1 to 40 C atoms that is optionally substituted and optionally contains one or more hetero atoms,
Ar⁴ and Ar⁵ are independently of each other mononuclear or polynuclear aryl or heteroaryl, which is optionally substituted and optionally fused to the 2,3-positions of one or both of the adjacent thiophene or selenophene groups,
c and e are independently of each other 0, 1, 2, 3 or 4, with 1<c+e≦6,
d and f are independently of each other 0, 1, 2, 3 or 4.

11. A device according to claim 1, characterized in that the copolymer comprises one or more repeat units selected from anthracene, benzanthracene, ketone, carbazole, fluorene, spirobifluorene, phenathrene, dehydrophenanthrene, triazine imidazole, pyridine, pyrimidine, pyridazine, pyrazine, oxadiazole, quinoline, quinoxaline, pyrene, perylene, benzimidazole, phosphinoxide, phenazine, phenanthroline, triarylborane and their derivatives, all of which are optionally substituted.

12. A device according to claim 1, characterized in that the copolymer is selected of the following formula 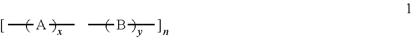
wherein
A is, in each case identically or different from each other, a unit of formula I,
B is, in each case identically or different from each other, selected from the repeating units anthracene, benzanthracene, ketone, carbazole, fluorene, spirobifluorene, phenathrene, dehydrophenanthrene, triazine imidazole, pyridine, pyrimidine, pyridazine, pyrazine, oxadiazole, quinoline, quinoxaline, pyrene, perylene, benzimidazole, phosphinoxide, phenazine, phenanthroline, triarylborane and their derivatives, all of which are optionally substituted,
or is, in each case identically or different from each other, a unit of formula II or III: 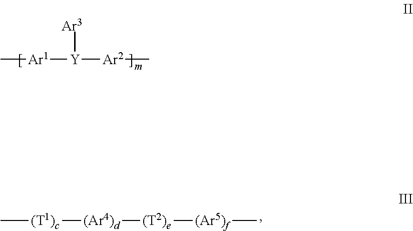
Y is N, P, P═O, PF₂, P═S, As, As═O, As═S, Sb, Sb═O or Sb═S, preferably N,
Ar¹ which may be the same or different, denote, independently if in different repeat units, a single bond or an optionally substituted mononuclear or polynuclear aryl or heteroaryl group,
Ar² which may be the same or different, denote, independently if in different repeat units, an optionally substituted mononuclear or polynuclear aryl or heteroaryl group,
Ar³ which may be the same or different, denote, independently if in different repeat units, an optionally substituted mononuclear or polynuclear aryl or heteroaryl group,
m is 1, 2 or 3,
T¹ and T² are independently of each other selected from thiophene, selenophene, thieno[2,3b]thiophene, thieno[3,2b]thiophene, dithienothiophene and pyrrole, all of which are optionally substituted with R⁵,
R⁵ is in each occurrence independently of each other selected from halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂—CF₃, —SF_{S}, optionally substituted silyl, or carbyl or hydrocarbyl with 1 to 40 C atoms that is optionally substituted and optionally contains one or more hetero atoms,
Ar⁴ and Ar⁵ are independently of each other mononuclear or polynuclear aryl or heteroaryl, which is optionally substituted and optionally fused to the 2,3-positions of one or both of the adjacent thiophene or selenophene groups,
c and e are independently of each other 0, 1, 2, 3 or 4, with 1<c+e≦6,
d and f are independently of each other 0, 1, 2, 3 or 4,
x is >0.05 and <1,
y is >0 and <0.95,
x+y is 1,
n is an integer >1.

13. A device according to claim 1, characterized in that the copolymer is selected of the following formula 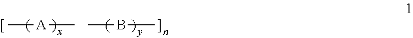
wherein
A is, in each case identically or different from each other, a unit of formula I,
B is, in each case identically or different from each other, selected from the repeating units anthracene, benzanthracene, ketone, carbazole, fluorene, spirobifluorene, phenathrene, dehydrophenanthrene, triazine imidazole, pyridine, pyrimidine, pyridazine, pyrazine, oxadiazole, quinoline, quinoxaline, pyrene, perylene, benzimidazole, phosphinoxide, phenazine, phenanthroline, triarylborane and their derivatives, all of which are optionally substituted,
or is, in each case identically or different from each other, a unit of formula II or III: 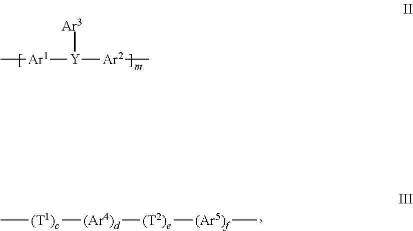
Y is N, P, P═O, PF₂, P═S, As, As═O, As═S, Sb, Sb═O or Sb═S, preferably N,
Ar¹ which may be the same or different, denote, independently if in different repeat units, a single bond or an optionally substituted mononuclear or polynuclear aryl or heteroaryl group,
Ar² which may be the same or different, denote, independently if in different repeat units, an optionally substituted mononuclear or polynuclear aryl or heteroaryl group,
Ar³ which may be the same or different, denote, independently if in different repeat units, an optionally substituted mononuclear or polynuclear aryl or heteroaryl group,
m is 1, 2 or 3,
T¹ and T² are independently of each other selected from thiophene, selenophene, thieno[2,3b]thiophene, thieno[3,2b]thiophene, dithienothiophene and pyrrole, all of which are optionally substituted with R⁵,
R⁵ is in each occurrence independently of each other selected from halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —SO₂R⁰, —OH, —NO₂—CF₃, —SF_{S}, optionally substituted silyl, or carbyl or hydrocarbyl with 1 to 40 C atoms that is optionally substituted and optionally contains one or more hetero atoms,
Ar⁴ and Ar⁵ are independently of each other mononuclear or polynuclear aryl or heteroaryl, which is optionally substituted and optionally fused to the 2,3-positions of one or both of the adjacent thiophene or selenophene groups,
c and e are independently of each other 0, 1, 2, 3 or 4, with 1<c+e≦6,
d and f are independently of each other 0, 1, 2, 3 or 4,
x is >0.05 and <1,
y is >0 and <0.95,
x+y is 1,
n is an integer >1.

14. An electronic device according to claim 12, characterized in that in formulae I and 1a-1e x=0.5 and y=0.5, and preferably the said functional layer is a hole transport layer.

15. A non-electroluminescent electronic device comprise:
an electrode,
a counter electrode, and
a functional layer provided between the said electrodes,
characterized in that the said functional layer comprises a copolymer as defined in claim 1.

16. A non-electroluminescent electronic device according to claim 15, characterized in that a charge generation layer (CGL) is provided between the said function layer and one of the said electrodes, wherein the CGL generates free charge carriers upon optical excitation, optionally and also preferably under an electric field.

17. A non-electroluminescent electronic device according to claim 15, which is an organic solar cell, a dye-sensitised solar cell, a field-quench device or a spintronic device.

18. Charge transport layer of an electronic device comprising a copolymer as defined in claim 1.
